(19) United States
(12) Patent Application Publication
(10) Pub. No.: US 2025/0089394 A1
(43) Pub. Date: Mar. 13, 2025

(54) IMAGE SENSOR AND METHOD FOR MANUFACTURING THE SAME

(71) Applicant: Samsung Electronics Co., Ltd., Suwon-si (KR)

(72) Inventors: Young Woo CHUNG, Suwon-si (KR); Soo Eon KIM, Suwon-si (KR); Yo Seph KIM, Suwon-si (KR); Chan Hyeon SEONG, Suwon-si (KR)

(73) Assignee: Samsung Electronics Co., Ltd., Suwon-si (KR)

(21) Appl. No.: 18/627,797

(22) Filed: Apr. 5, 2024

(30) Foreign Application Priority Data
Sep. 11, 2023 (KR) 10-2023-0120247

(51) Int. Cl. H01L 27/146

(52) U.S. Cl. CPC H10F 39/807; H10F 39/011; H10F 39/182; H10F 39/8053; H10F 39/8063

(57) ABSTRACT

An image sensor and a manufacturing method thereof are provided. The image sensor includes a substrate including first and second surfaces opposed to each other, a first pixel group in the substrate including a first to forth unit pixels adjacent to one another in a plan view, a photoelectric conversion area in the first to fourth unit pixels, a first isolation trench in the substrate surrounding the first pixel group, a second isolation trench in the substrate between the first unit pixel and the fourth unit pixel and between the second unit pixel and the third unit pixel, the second isolation trench in contact with the second surface of the substrate, and a first color filter on the second surface of the substrate covering the first pixel group.

### CROSS-REFERENCE TO RELATED APPLICATION

This application claims priority from Korean Patent Application No. 10-2023-0120247 filed on Sep. 11, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to image sensors and methods for manufacturing the same. More specifically, the present disclosure relates to CMOS-type image sensors.

### Description of Related Art

An image sensor is a semiconductor device that converts optical information into an electrical signal. The image sensor may include a CCD (Charge Coupled Device) image sensor and a CMOS (Complementary Metal-Oxide Semiconductor) type image sensor.

The image sensor may be constructed in a form of a package, where the package may be structured to protect the image sensor and at the same time may be constructed such that light is incident on a light-receiving surface photo or a sensing area of the image sensor.

### SUMMARY

Aspects of the present disclosure provide image sensors with improved performance and integration.

Other aspects of the present disclosure provide methods for manufacturing an image sensor with improved performance and integration.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some aspects of the present inventive concepts, there is provided an image sensor including a substrate including a first surface and a second surface opposed to each other, a first pixel group in the substrate, the first pixel group including a first unit pixel, a second unit pixel adjacent to the first unit pixel in a first direction in a plan view, a third unit pixel adjacent to the first unit pixel in a second direction perpendicular to the first direction in the plan view, and a fourth unit pixel adjacent to the second unit pixel in the second direction in the plan view and adjacent to the third unit pixel in the first direction in the plan view, a photoelectric conversion area in each of the first to fourth unit pixels, a first isolation trench in the substrate, the first isolation trench surrounding the first pixel group, a second isolation trench in the substrate, the second isolation trench between the first unit pixel and the fourth unit pixel and between the second unit pixel and the third unit pixel, wherein the second isolation trench is in contact with the second surface of the substrate, and a first color filter on the second surface of the substrate, the first color filter covering the first pixel group.

According to some aspects of the present inventive concepts, there is provided an image sensor including a substrate including a first surface and a second surface opposed to each other, a first isolation trench defining a plurality of pixel groups in the substrate, each of the pixel groups includes a plurality of unit pixels, a second isolation trench in each of the pixel groups, the second isolation trench extending from the second surface and is spaced apart from the first surface, a photoelectric conversion area in each of the unit pixels, circuit elements on the first surface of the substrate, and color filters on the second surface of the substrate, wherein the plurality of unit pixels includes a first unit pixel, a second unit pixel adjacent to the first unit pixel in a first direction, and a third unit pixel adjacent to the first unit pixel in a second direction intersecting the first direction, wherein the second isolation trench is between the second unit pixel and the third unit pixel.

According to some aspects of the present inventive concepts, there is provided an image sensor including a substrate including a first surface and a second surface opposed to each other, a first pixel group in the substrate, the first pixel group including a first unit pixel, a second unit pixel adjacent to the first unit pixel in a first direction, a third unit pixel adjacent to the first unit pixel in a second direction intersecting the first direction, and a fourth unit pixel adjacent to the second unit pixel in the second direction and adjacent to the third unit pixel in the first direction, a photoelectric conversion area in each of the first to fourth unit pixels, a first isolation trench in the substrate, the first isolation trench surrounding the first pixel group, a second isolation trench in the substrate, the second isolation trench between the first unit pixel and the fourth unit pixel, a floating diffusion area extending from the first surface in the substrate, at least a portion of the floating diffusion area overlapping the second isolation trench in a third direction intersecting the first direction and the second direction, a transfer transistor on the first surface of each of the first to fourth unit pixels, the transfer transistor being adjacent to the floating diffusion area, a first color filter on the second surface of the substrate, the first color filter covering the first pixel group and having a first color, and a micro lens on the first color filter, wherein the second isolation trench extends from the second surface and is spaced apart from the floating diffusion area.

### BRIEF DESCRIPTION OF DRAWINGS

The above and other aspects and features of the present disclosure will become more apparent by describing in detail illustrative embodiments thereof with reference to the attached drawings, in which:

FIG. 1 is an illustrative block diagram for illustrating an image sensor according to some example embodiments.

FIG. 2 is an illustrative circuit diagram for illustrating a unit pixel of an image sensor according to some example embodiments.

FIG. 3 is a layout diagram for illustrating an image sensor according to some example embodiments.

FIG. 4 is a schematic cross-sectional view cut along a line A-A in FIG. 3.

FIG. 5 is a schematic cross-sectional view cut along a line B-B in FIG. 3.

FIG. 6 is a schematic cross-sectional view cut along a line C-C in FIG. 3.

FIG. 7 is a cross-sectional view for illustrating an effect of the image sensor of FIG. 3 to FIG. 6.

FIG. 8 to FIG. 10 are cross-sectional views for illustrating an image sensor according to some example embodiments.

FIG. 11 is a cross-sectional view for illustrating an image sensor according to some example embodiments.

FIG. 12 to FIG. 14 are various layout diagrams for illustrating an image sensor according to some example embodiments.

FIG. 15 is a schematic layout diagram for illustrating an image sensor according to some example embodiments.

FIG. 16 is a schematic cross-sectional view for illustrating the image sensor in FIG. 15.

FIG. 17 to FIG. 24 are drawings of intermediate structures corresponding to intermediate steps of the manufacturing method of the image sensor according to some example embodiments.

FIG. 25 to FIG. 30 are drawings of intermediate structures corresponding to intermediate steps of a method for manufacturing an image sensor according to some example embodiments.

### DETAILED DESCRIPTIONS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

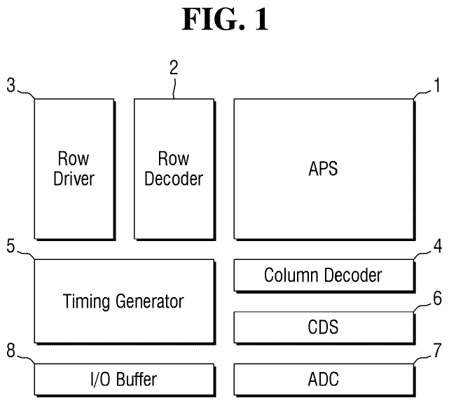

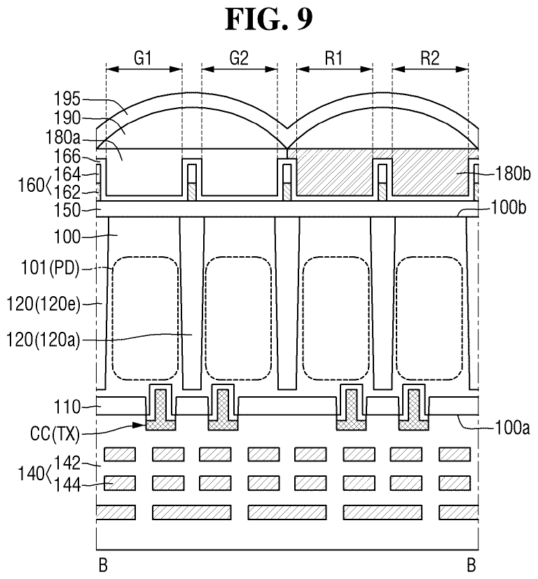

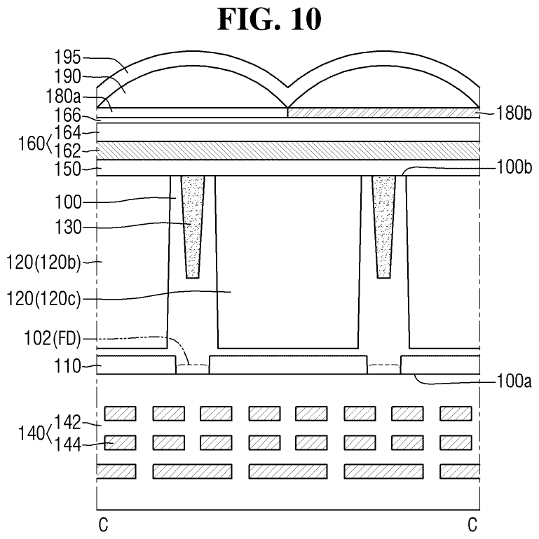

Hereinafter, with reference to FIGS. 1 to FIG. 16, an image sensor according to some example embodiments is described.

FIG. 1 is an illustrative block diagram for illustrating an image sensor according to some example embodiments.

Referring to FIG. 1, the image sensor according to some example embodiments includes an active pixel sensor array (APS) 1, a row decoder 2, a row driver 3, a column decoder 4, a timing generator 5, a correlated double sampler (CDS) 6, an analog-to-digital converter (ADC) 7, and an input/output buffer (I/O Buffer) 8.

The active pixel sensor array 1 includes a plurality of unit pixels arranged two-dimensionally and may convert an optical signal into an electrical signal. The active pixel sensor array 1 may operate based on a plurality of driving signals such as a pixel select signal, a reset signal, and a charge transfer signal from the row driver 3. Furthermore, an electrical signal generated from the active pixel sensor array 1 may be provided to the correlated double sampler 6.

The row driver 3 may provide the plurality of driving signals for driving the plurality of unit pixels to the active pixel sensor array 1 according to a decoding result from the row decoder 2. When the unit pixels are arranged in a matrix form, the driving signals may be provided on each row basis.

The timing generator 5 may provide a timing signal and a control signal to the row decoder 2 and the column decoder 4.

The correlated double sampler (CDS) 6 may receive the electrical signal generated from the active pixel sensor array 1 and perform hold and sampling on the received electrical signal. The correlative double sampler 6 may double-sample a specific noise level and a signal level resulting from the electrical signal and output a difference level corresponding to a difference between the noise level and the signal level.

The analog to digital converter (ADC) 7 may convert an analog signal corresponding to the difference level output from correlated double sampler 6 into a digital signal and output the digital signal.

The input/output buffer 8 may latch the digital signal, and may sequentially output the latched digital signal to an image signal processor (not shown) according to a decoding result from the column decoder 4.

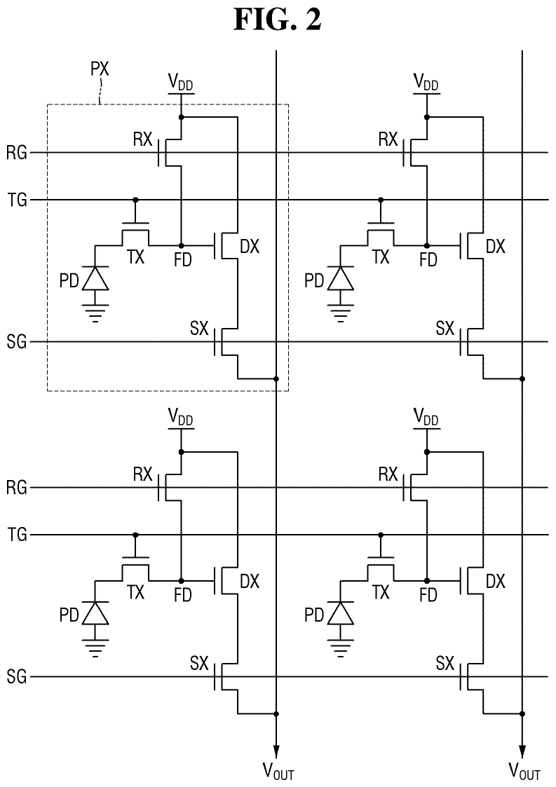

FIG. 2 is an illustrative circuit diagram for illustrating a unit pixel of an image sensor according to some example embodiments.

Referring to FIG. 2, an image sensor according to some example embodiments includes a plurality of unit pixels PX.

The plurality of unit pixels PX may be arranged two-dimensionally, for example, in a matrix form. Each unit pixel PX may include a photoelectric conversion element PD, a transfer transistor TX, a floating diffusion area FD, a reset transistor RX, a drive transistor DX and a select transistor SX.

The photoelectric conversion element PD may generate charges in proportion to an amount of light incident from an outside. The photoelectric conversion element PD may be coupled with the transfer transistor TX which transfers the generated and accumulated charges to the floating diffusion area FD. The floating diffusion area FD is an area that converts the charges into voltage. Because the floating diffusion area FD has parasitic capacitance, charges may be stored therein in an accumulated manner.

One end of the transfer transistor TX may be connected to the photoelectric conversion element PD, and the other end of the transfer transistor TX may be connected to the floating diffusion area FD. The transfer transistor TX may be embodied as a transistor operating based on a predetermined (or, alternatively, desired or selected) bias (for example, a transfer signal TG). In other words, the transfer transistor TX may transfer the charge generated from the photoelectric conversion element PD to the floating diffusion area FD based on the transfer signal TG.

The drive transistor DX may be embodied as a source follower buffer amplifier. The drive transistor DX may amplify a change in an electrical potential of the floating diffusion area FD having received the charges from the photoelectric conversion element PD and output the amplified change to an output line Vour. When the drive transistor DX is turned on, a predetermined (or, alternatively, desired or selected) electrical potential provided to a drain of the drive transistor DX, for example, a power voltage VDD may be transferred to a drain area of the select transistor SX.

The select transistor SX may select the unit pixel PX to be read on a row basis. The select transistor SX may be embodied as a transistor operating based on a predetermined (or, alternatively, desired or selected) bias (for example, a row select signal SG) applied from a select line.

The reset transistor RX may periodically reset the floating diffusion area FD. The reset transistor RX may be embodied as a transistor operating based on a predetermined (or, alternatively, desired or selected) bias (for example, a reset signal RG) applied from a reset line. When the reset transistor RX is turned on based on the reset signal RG, the predetermined (or, alternatively, desired or selected) electrical potential provided to a drain of the reset transistor RX, for example, the power supply VDD may be transferred to the floating diffusion area FD, so that the floating diffusion area FD may be reset.

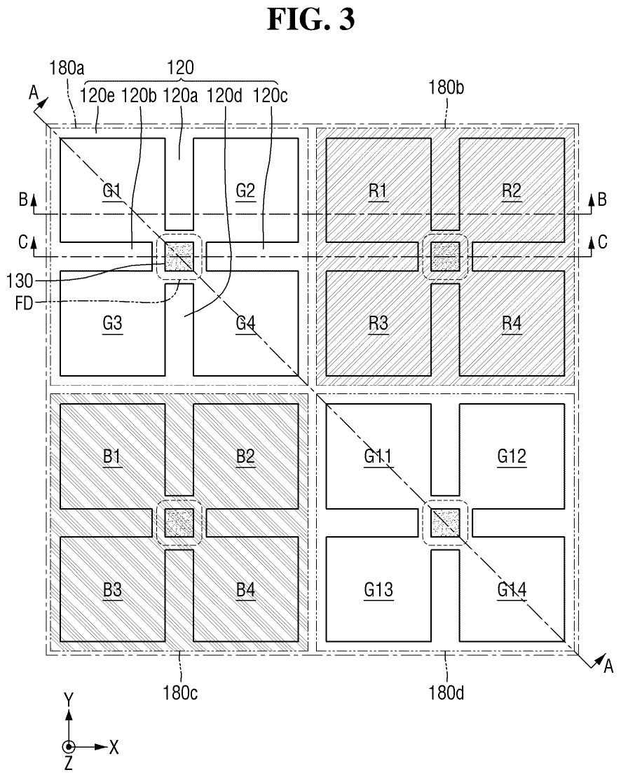

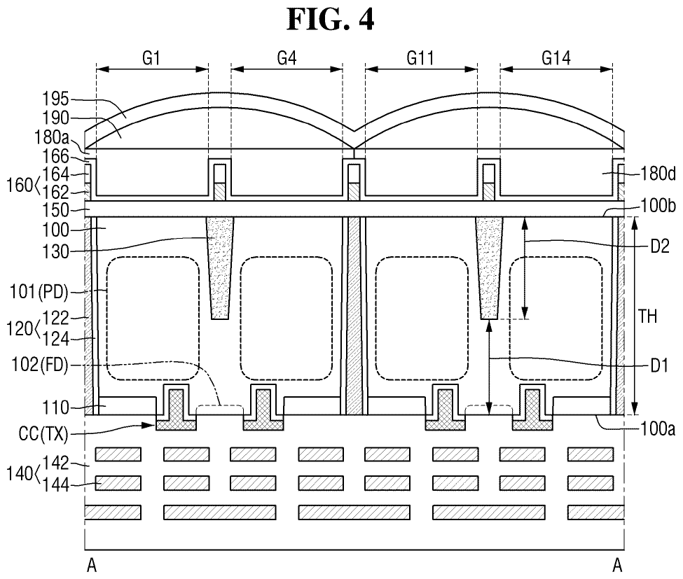

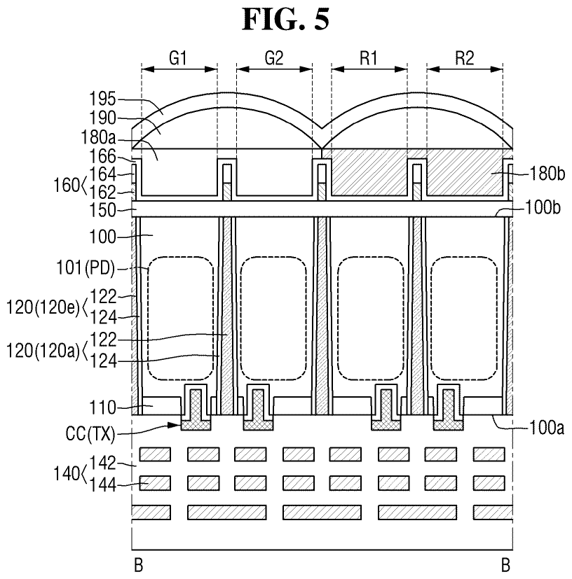

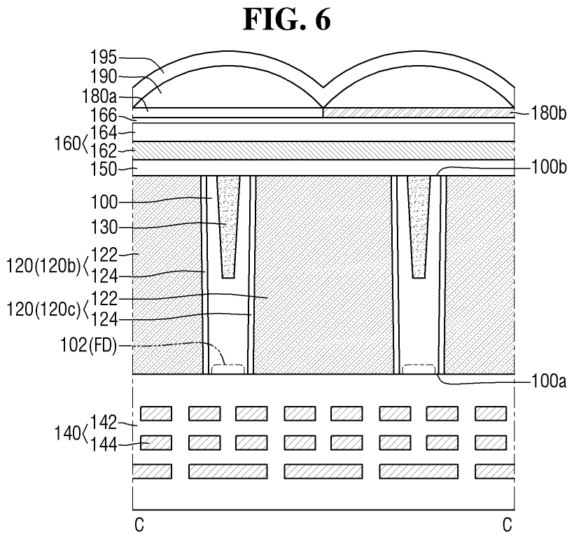

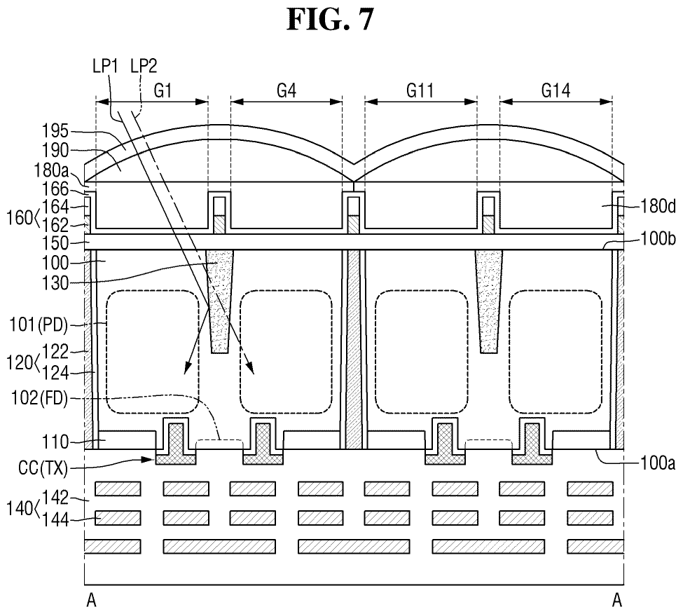

FIG. 3 is a layout diagram for illustrating an image sensor according to some example embodiments. FIG. 4 is a schematic cross-sectional view cut along a line A-A in FIG. 3. FIG. 5 is a schematic cross-sectional view cut along a line B-B in FIG. 3. FIG. 6 is a schematic cross-sectional view cut along a line C-C in FIG. 3. FIG. 7 is a cross-sectional view for illustrating an effect of the image sensor of FIG. 3 to FIG. 6.

Referring to FIG. 3 to FIG. 7, the image sensor according to some example embodiments includes a first substrate 100, a photoelectric conversion area 101, an element isolation film 110, a first circuit element CC, a first isolation pattern 120 (also referred to as a first isolation trench 120), a second isolation pattern 130 (also referred to as a second isolation trench 130), a first wiring structure 140, a surface insulating film 150, a grid pattern 160, a first protective film 166, color filters 180a to 180d and a micro lens 190.

The first substrate 100 may be a semiconductor substrate. For example, the first substrate 100 may be made of bulk silicon or SOI (silicon-on-insulator). The first substrate 100 may be a silicon substrate, or may include a material other than silicon, such as silicon germanium, indium antimonide, lead telluride compound, indium arsenide, indium phosphide, gallium arsenide, or gallium antimonide. Alternatively, the first substrate 100 may have a base substrate and an epitaxial layer formed on the base substrate.

The first substrate 100 may include a first surface 100a and a second surface 100b, which are opposite to each other. In some example embodiments as described later, the first surface 100a may also be referred to as a front surface of the first substrate 100, and the second surface 100b may also be referred to as a rear or back surface of the first substrate 100. In some example embodiments, the second surface 100b of the first substrate 100 may be a light-receiving surface on which light is incident. That is, the image sensor according to some example embodiments may be a back side illuminated (BSI) image sensor.

In some example embodiments, the first substrate 100 may contain impurities of a first conductivity type. In some example embodiments as described later, some example embodiments in which the first conductivity type is a p-type is described. However, this is only an example, and the inventive concepts are not limited thereto, for example the first conductivity type may be a n-type.

In some example embodiments, a thickness TH of the first substrate 100 may be in a range of about or exactly 2 μm to about or exactly 10 μm. In this regard, the thickness TH of the first substrate 100 refers to a thickness in a third direction Z that intersects the first surface 100a and/or the second surface 100b. In some example embodiments, the thickness TH of the first substrate 100 may be in a range of about or exactly 2 μm to about or exactly 5 μm.

In the first substrate 100, a plurality of pixel groups may be formed. The plurality of pixel groups may be arranged two-dimensionally, for example, in a matrix form, on a plane including a first direction X and a second direction Y (or a plane intersecting the third direction Z).

For example, the plurality of pixel groups may include a first pixel group G1 to G4, a second pixel group R1 to R4, a third pixel group B1 to B4, and a fourth pixel group G11 to G14 that are adjacent to each other. The second pixel group R1 to R4 may be adjacent to the first pixel group G1 to G4 in the first direction X. The third pixel group B1 to B4 may be adjacent to the first pixel group G1 to G4 in the second direction Y. The fourth pixel group G11 to G14 may be adjacent to the second pixel group R1 to R4 in the second direction Y, and may be adjacent to the third pixel group B1 to B4 in the first direction X. That is, the fourth pixel group G11 to G14 may be adjacent to the first pixel group G1 to G4 in a diagonal direction between the first direction X and the second direction Y.

Each pixel group may include a plurality of unit pixels. For example, the first pixel group G1 to G4 may include first to fourth unit pixels G1 to G4, the second pixel group R1 to R4 may include fifth to eighth unit pixels R1 to R4, the third pixel group B1 to B4 may include 9th to 12th unit pixels B1 to B4, and the fourth pixel group G11 to G14 may include 13th to 16th unit pixels G11 to G14.

The plurality of unit pixels G1 to G4, R1 to R4, B1 to B4, or G11 to G14 may be arranged two-dimensionally, for example, in a matrix form in a plane including the first direction X and the second direction Y (or a plane intersecting the third direction Z).

In some example embodiments, the second unit pixel G2 may be adjacent to the first unit pixel G1 in the first direction X. The third unit pixel G3 may be adjacent to the first unit pixel G1 in the second direction Y. The fourth unit pixel G4 may be adjacent to the second unit pixel G2 in the second direction Y, and may be adjacent to the third unit pixel G3 in the first direction X. That is, the fourth unit pixel G4 may be adjacent to the first unit pixel G1 in the diagonal direction between the first direction X and the second direction Y.

The photoelectric conversion area 101 may be formed in the first substrate 100. The photoelectric conversion area 101 may be formed in each of the unit pixels G1 to G4, R1 to R4, B1 to B4, and G11 to G14 arranged in the first substrate 100. For example, a plurality of photoelectric conversion areas 101 corresponding to the plurality of unit pixels G1 to G4, R1 to R4, B1 to B4, and G11 to G14 may be arranged two-dimensionally (for example, in a matrix form) within the first substrate 100.

The photoelectric conversion area 101 may correspond to a photoelectric conversion clement PD in FIG. 2. In other words, the photoelectric conversion area 101 may generate charges in proportion to the amount of light incident from the outside. For example, the photoelectric conversion area 101 may include a photo diode, a photo transistor, a photo gate, a pinned photo diode (PPD) or a combination thereof. However, the present disclosure is not limited thereto.

The photoelectric conversion area 101 may have a second conductivity type that is different from the first conductivity type. For example, the photoelectric conversion area 101 may be formed by ion implanting n-type impurities into the first substrate 100 of the p-type.

The element isolation film 110 may be formed in the first substrate 100. The element isolation film 110 may define an active area 102 within each of the unit pixels G1 to G4, R1 to R4, B1 to B4, and G11 to G14. The element isolation film 110 may extend along and on the first surface 100a of the first substrate 100, and may define the active area 102 extending on and along the first surface 100a and within the first substrate 100. The element isolation film 110 may include an insulating material, for example, at least one of silicon oxide, silicon nitride, silicon oxynitride, and a combination thereof. However, the present disclosure is not limited thereto.

The active area 102 may include the floating diffusion area FD. The floating diffusion area FD may have the second conductivity type that is different from the first conductivity type. For example, the floating diffusion area FD may be formed by ion implanting n-type impurities into the first substrate 100 of the p-type.

In some example embodiments, adjacent unit pixels of each pixel group may share the floating diffusion area FD. For example, the floating diffusion area FD may be interposed between unit pixels adjacent to each other in the diagonal direction. In some example embodiments, the floating diffusion area FD of the first pixel group G1 to G4 may be interposed between the first unit pixel G1 and fourth unit pixel G4 and/or between the second unit pixel G2 and third unit pixel G3. That is, the floating diffusion area FD of the first pixel group G1 to G4 may be positioned at a center of the first to fourth unit pixels G1 to G4. The first to fourth unit pixels G1 to G4 may share the floating diffusion area FD positioned at the center thereof.

The first circuit element CC may be formed on the first surface 100a of the first substrate 100. The first circuit element CC may include various transistors for processing an electrical signal generated from each of the unit pixels G1 to G4, R1 to R4, B1 to B4, and G11 to G14 within the first substrate 100. For example, the first circuit element CC may include the transfer transistor TX, the reset transistor RX, the drive transistor DX, and/or the select transistor SX, etc. as described above in the description of FIG. 2.

In some example embodiments, the first circuit element CC may include a vertical transfer transistor. For example, as shown in FIG. 4 and FIG. 5, a portion of the transfer transistor TX of the first circuit element CC may extend into the first substrate 100 and toward the photoelectric conversion area 101. The transfer transistor TX may reduce an area size of the unit pixel, thereby contributing to high integration of the image sensor.

The first isolation pattern 120 may be formed in the first substrate 100. The first isolation pattern 120 may define the plurality of pixel groups within the first substrate 100. For example, the first isolation pattern 120 may surround each of the first pixel group G1 to G4, the second pixel group R1 to R4, the third pixel group B1 to B4, and the fourth pixel group G11 to G14 in a plan view.

The first isolation pattern 120 may prevent or reduce photocharges generated from a specific pixel group (such as the first pixel group G1 to G4) from migrating to another pixel group (such as the second pixel group R1 to R4) adjacent thereto in a random-drift manner. The first isolation pattern 120 may include an insulating material, for example, at least one of silicon oxide, silicon nitride, silicon oxynitride, and combinations thereof. However, the present disclosure is not limited thereto.

In some example embodiments, the first isolation pattern 120 may include a low refractive index material having a lower refractive index than that of silicon (Si), for example, at least one of silicon oxide, aluminum oxide, tantalum oxide, and combinations thereof. The first isolation pattern 120 may refract or reflect light incident at an angle onto the second surface 100b as a light-receiving surface to improve light collection efficiency.

In some example embodiments, the first isolation pattern 120 may be formed so as to be absent in the center of adjacent unit pixels in each pixel group. For example, the first isolation pattern 120 may include first to fourth pixel isolation portions 120a to 120d (also referred to as first to fourth pixel isolation trenches 120a to 120d) and a group isolation portion 120c (also referred to as a group isolation trench 120c).

The group isolation portion 120c may surround each pixel group in a plan view. In some example embodiments, the group isolation portion 120e may surround the first pixel group G1 to G4. Each of the first to fourth pixel isolation portions 120a to 120d may protrude from the group isolation portion 120c so as to be interposed between adjacent unit pixels. In some example embodiments, the first pixel isolation portion 120a may extend from the group isolation portion 120e in the second direction Y so as to be interposed between the first unit pixel G1 and the second unit pixel G2. In some example embodiments, the second pixel isolation portion 120b may extend from the group isolation portion 120e in the first direction X so as to be interposed between the first unit pixel G1 and the third unit pixel G3. In some example embodiments, the third pixel isolation portion 120c may extend from the group isolation portion 120e in the first direction X so as to be interposed between the second unit pixel G2 and the fourth unit pixel G4. In some example embodiments, the fourth pixel isolation portion 120d may extend from the group isolation portion 120e in the first direction X so as to be interposed between the third unit pixel G3 and the fourth unit pixel G4.

In some example embodiments, the floating diffusion area FD may be interposed between the first pixel isolation portion 120a and the fourth pixel isolation portion 120d and between the second pixel isolation portion 120b and the third pixel isolation portion 120c.

In some example embodiments, the first isolation pattern 120 may extend from the first surface 100a of the first substrate 100. In some example embodiments, a width of the first isolation pattern 120 may decrease as the first isolation pattern 120 extends from the first surface 100a toward the second surface 100b. For example, the first isolation pattern 120 may be formed by burying an insulating material into a deep trench formed by patterning a portion of the first substrate 100 including the first surface 100a.

In some example embodiments, the first isolation pattern 120 may extend through an entirety of the first substrate 100 in the third direction Z. For example, the first isolation pattern 120 may not be covered with the second surface 100b of the first substrate 100 so as to be exposed.

In some example embodiments, the first isolation pattern 120 may include a filling pattern 122 and a spacer film 124.

The filling pattern 122 may extend from the first surface 100a of the first substrate 100 toward the second surface 100b of the first substrate 100. The filling pattern 122 may include a conductive material, for example, polysilicon (poly Si). However, the present disclosure is not limited thereto. In some example embodiments, a ground voltage or a negative voltage may be applied to the filling pattern 122. This filling pattern 122 may prevent or reduce charges generated under ESD (electrostatic discharge) from accumulating on a surface of the first substrate 100 (for example, the second surface 100b) to effectively prevent or reduce ESD bruise defect.

The spacer film 124 may extend along a side surface of the filling pattern 122. The spacer film 124 may include an insulating material such as at least one of silicon oxide, aluminum oxide, tantalum oxide, and combinations thereof. However, the present disclosure is not limited thereto. The spacer film 124 may be interposed between the filling pattern 122 and the first substrate 100 so as to electrically insulate the filling pattern 122 and the first substrate 100 from each other.

In some example embodiments, the spacer film 124 may be formed as a multilayer. In some example embodiments, the multilayer of the spacer film 124 may include at least one of silicon oxide, aluminum oxide, tantalum oxide, and combinations thereof.

The second isolation pattern 130 may be formed in the first substrate 100. The second isolation pattern 130 may be positioned in each pixel group. The second isolation pattern 130 may be interposed between unit pixels adjacent to each other in the diagonal direction. In some example embodiments, the second isolation pattern 130 of the first pixel group G1 to G4 may be interposed between the first unit pixel G1 and fourth unit pixel G4 and/or between the second unit pixel G2 and third unit pixel G3. That is, the second isolation pattern 130 of the first pixel group G1 to G4 may be positioned in a center of the first to fourth unit pixel G1 to G4.

The second isolation pattern 130 may prevent or reduce photocharges generated from a specific unit pixel (such as the first unit pixel G1) from moving to another unit pixel adjacent thereto in the diagonal direction (such as the fourth unit pixel G4) in a random drift manner. The second isolation pattern 130 may include an insulating material such as at least one of silicon oxide, silicon nitride, silicon oxynitride, and combinations thereof. However, the present disclosure is not limited thereto.

In some example embodiments, the second isolation pattern 130 may include a low refractive index material having a lower refractive index than that of silicon (Si), for example, at least one of silicon oxide, aluminum oxide, tantalum oxide, and combinations thereof. The second isolation pattern 130 may refract or reflect light incident at an angle to the second surface 100b as a light-receiving surface to improve light collection efficiency.

In some example embodiments, the second isolation pattern 130 may be interposed between the first pixel isolation portion 120a and the fourth pixel isolation portion 120d and between the second pixel isolation portion 120b and the third pixel isolation portion 120c.

It is shown that a width of the second isolation pattern 130 in the first direction X is equal to a width of the first pixel isolation portion 120a (or a width of the fourth pixel isolation portion 120d) in the first direction X, and a width of the second isolation pattern 130 in the second direction Y is equal to a width of the second pixel isolation portion 120b (or a width of the third pixel isolation portion 120c) in the second direction Y. However, this is only an example and the inventive concepts are not limited thereto. In another example, the width of the second isolation pattern 130 may be different from the width of each of the first to fourth pixel isolation portions 120a to 120d.

Furthermore, the second isolation pattern 130 is shown to be spaced from the first isolation pattern 120 in a plan view. However, this is only an example and the inventive concepts are not limited thereto. In another example, a portion of the second isolation pattern 130 may overlap with a portion of the first isolation pattern 120 in the third direction Z.

In some example embodiments, the second isolation pattern 130 may extend from the second surface 100b of the first substrate 100. A width of the second isolation pattern 130 may decrease as the second isolation pattern 130 extends from the second surface 100b to the first surface 100a. For example, the second isolation pattern 130 may be formed by burying an insulating material in a deep trench formed by patterning a portion of the first substrate 100 including the second surface 100b. For example, a depth D2 of the second isolation pattern 130 from the second surface 100b of the first substrate 100 may be about or exactly 0.5 μm or larger (such as up to about or exactly 10 μm).

In some example embodiments, the second isolation pattern 130 may not extend through an entirety of the first substrate 100. For example, the second isolation pattern 130 may be spaced from the first surface 100a of the first substrate 100. For example, a distance D1 by which the second isolation pattern 130 is spaced from the first surface 100a of the first substrate 100 may be about or exactly 1 μm or larger (such as up to about or exactly 10 μm).

In some example embodiments, at least a portion of the floating diffusion area FD may overlap the second isolation pattern 130 in the third direction Z. In some example embodiments, as described above, both the second isolation pattern 130 and the floating diffusion area FD of the first pixel group G1 to G4 may be positioned in the center of the first to fourth unit pixel G1 to G4 in a plan view. In some example embodiments, the second isolation pattern 130 may be spaced from the active area 102 (e.g., the floating diffusion area FD) in the third direction Z.

In some example embodiments, the depth D2 of the second isolation pattern 130 may be in a range of about or exactly 50% to about or exactly 80% of the thickness TH of the first substrate 100. When the depth D2 of the second isolation pattern 130 is equal to or larger than about or exactly 50% of the thickness TH of the first substrate 100 (for example, up to about or exactly 80%), the second isolation pattern 130 may effectively prevent or reduce optical cross-talk between unit pixels adjacent to each other in the diagonal direction. Furthermore, when the depth D2 of the second isolation pattern 130 is smaller than or equal to about or exactly 80% of the thickness TH of the first substrate 100, damage to the element (such as damage to the floating diffusion area FD) due to the formation of the second isolation pattern 130 may be prevented or reduced effectively. For example, when the thickness TH of the first substrate 100 is in a range of about or exactly 2 μm to about or exactly 5 μm, the depth D2 of the second isolation pattern 130 may be in a range of about or exactly 1 μm to about or exactly 4 μm.

The first wiring structure 140 may be formed on the first surface 100a of the first substrate 100. The first wiring structure 140 may include the plurality of wiring patterns. For example, the first wiring structure 140 may include a first inter-wiring insulating film 142 on the first surface 100a, and a first wiring pattern 144 within the first inter-wiring insulating film 142. In FIG. 4 to FIG. 6, the number of layers and arrangement of the first wiring pattern 144 are illustrative only and are not limited to those shown FIG. 4 to FIG. 6. The first wiring structure 140 may be electrically connected to the first circuit element CC and may transmit and communicate the electrical signal with each of the unit pixels G1 to G4, R1 to R4, B1 to B4, and G11 to G14 via the first circuit element CC.

The surface insulating film 150 may be formed on the second surface 100b of the first substrate 100. The surface insulating film 150 may conformally extend along the second surface 100b of the first substrate 100. The surface insulating film 150 may include an insulating material such as at least one of silicon oxide, silicon nitride, silicon oxynitride, aluminum oxide, hafnium oxide, and combinations thereof. However, the present disclosure is not limited thereto.

The surface insulating film 150 may act as an anti-reflection film and may prevent or reduce reflection of light incident on the second surface 100b as a light-receiving surface. Thus, a light reception percentage of the photoelectric conversion area 101 may be improved. Alternatively, the surface insulating film 150 may act as a planarization film to allow the color filters 180a to 180d and the micro lenses 190 which will be described later to have a uniform height.

In some example embodiments, the surface insulating film 150 may be formed as a multilayer. In some example embodiments, unlike what is shown, the surface insulating film 150 may include an aluminum oxide film, a hafnium oxide film, a silicon oxide film, a silicon nitride film, and a hafnium oxide film that are sequentially stacked on the second surface 100b of the first substrate 100.

The grid pattern 160 may be formed on surface insulating film 150. The grid pattern 160 may surround each of the unit pixels G1 to G4, R1 to R4, B1 to B4, and G11 to G14 while being disposed on the first substrate 100. For example, the grid pattern 160 may be formed in a grid manner and on the surface insulating film 150 and may surround each of the unit pixels G1 to G4, R1 to R4, B1 to B4, and G11 to G14 arranged in a matrix form. In some example embodiments, the grid pattern 160 may be positioned so as to overlap the first isolation pattern 120 and the second isolation pattern 130 in the third direction Z.

In some example embodiments, the grid pattern 160 may include a metal pattern 162 and a low refractive index pattern 164. The metal pattern 162 and the low refractive index pattern 164 may be sequentially stacked on the surface insulating film 150.

The metal pattern 162 may include, but is limited to, at least one of, for example, titanium (Ti), titanium nitride (TiN), tantalum (Ta), tantalum nitride (TaN), tungsten (W), aluminum (Al), copper (Cu), and combinations thereof. The metal pattern 162 may prevent or reduce charges generated under the ESD electrostatic discharge from accumulating on the surface of the first substrate 100 (such as the second surface 100b), thereby effectively preventing or reducing the ESD bruise defect.

The low refractive index pattern 164 may include a low refractive index material with a lower refractive index than that of silicon (Si). For example, the low refractive index pattern 164 may include at least one of silicon oxide, aluminum oxide, tantalum oxide, and combinations thereof. However, the present disclosure is not limited thereto. The low refractive index pattern 164 may refract or reflect light incident at an angle to the second surface 100b as the light receiving surface to improve light collection efficiency.

The first protective film 166 may be formed on the surface insulating film 150 and the grid pattern 160. The first protective film 166 may extend conformally along a profile of each of the surface insulating film 150 and the grid pattern 160. The first protective film 166 may prevent or reduce damage to the surface insulating film 150 and the grid pattern 160. The first protective film 166 may include, for example, aluminum oxide (AlO). However, the present disclosure is not limited thereto.

The color filters 180a to 180d may be formed on the first protective film 166. The color filters 180a to 180d may have various colors depending on the unit pixels. For example, the color filters 180a to 180d may include a red color filter, a green color filter, a blue color filter, a yellow filter, a magenta filter, and a cyan filter, and may further include a white filter.

In some example embodiments, the unit pixels of each pixel group may share a color filter of the same color. Furthermore, the color filter of one pixel group may have a different color from a color of the color filter of another pixel group adjacent thereto. For example, the color filters 180a to 180d may include the first color filter 180a, the second color filter 180b, the third color filter 180c, and the fourth color filter 180d that are adjacent to each other. The first color filter 180a may have a first color and cover the first to fourth unit pixels G1 to G4. The second color filter 180b may cover the fifth to eighth unit pixels R1 to R4 and have a second color different from the first color. The third color filter 180c may cover the 9th to 12th unit pixels B1 to B4 and have a third color that is different from the first color. The fourth color filter 180d may cover the 13th to 16th unit pixels G11 to G14 and have a fourth color different from the second color and the third color.

In some example embodiments, the color filters 180a to 180d may be arranged in a Bayer pattern. In some example embodiments, each of the first color filter 180a and the fourth color filter 180d may be a green color filter, the second color filter 180b may be a red color filter, and the third color filter 180c may be a blue color filter.

The micro lens 190 may be formed on the color filters 180a to 180d. The micro lens 190 has a convex shape and may have a predetermined (or, alternatively, desired or selected) radius of curvature. Accordingly, the micro lens 190 may condense light to be incident on the photoelectric conversion area 101. The micro lens 190 may include, for example, a light-transmissive resin. However, the present disclosure is not limited thereto.

In some example embodiments, the unit pixels of each pixel group may share one micro lens 190. For example, the micro lens 190 may be positioned to overlap each pixel group. Thus, each pixel group may provide an auto-focus (AF) function. In some example embodiments, the first pixel group G1 to G4 may provide a phase detection AF (PDAF) function using divided photoelectric conversion areas 101 of the first to fourth unit pixels G to G4.

The second protective film 195 may be formed on the micro lens 190. The second protective film 195 may extend along a top surface of the micro lens 190. The second protective film 195 may include an inorganic oxide film such as a silicon oxide film, a titanium oxide film, a zirconium oxide film, or a hafnium oxide film. However, the present disclosure is not limited thereto. In some example embodiments, the second protective film 195 may include a low temperature oxide (LTO).

The second protective film 195 may protect the micro lens 190 from the outside. For example, the second protective film 195 may include the inorganic oxide film to protect the micro lens 190 including an organic material. Furthermore, the second protective film 195 may improve the quality of the image sensor by improving light-condensing efficiency of the micro lens 190. For example, the second protective film 195 may fill a space between the micro lenses 190 to reduce reflection, refraction, scattering, etc. of incident light reaching the space between the micro lenses 190.

In order to improve the performance of the image sensor, a structure in which a color filter of the same color is placed on the plurality of unit pixels that are adjacent to each other (for example, a so-called Qcell (Quad Cell) structure in which a color filter of the same color is placed on four adjacent unit pixels) has been proposed. In this structure, the first isolation pattern 120 which is absent in the center of the adjacent unit pixels may improve an area size of the light-receiving surface on which light is incident, thereby further improving sensitivity of the image sensor. However, the center area of the adjacent unit pixels in which the first isolation pattern 120 is absent may cause optical cross-talk between the unit pixels adjacent to each other in the diagonal direction.

Thus, in the image sensor according to some example embodiments, the second isolation pattern 130 may be disposed in the center area of the adjacent unit pixels in which the first isolation pattern 120 is absent, thereby effectively preventing or reducing the optical crosstalk between the unit pixels adjacent to each other in the diagonal direction. For example, as shown by a first optical path LP1 in FIG. 7, the first isolation pattern 120 may induce total reflection of light incident obliquely on the second surface 100b of the first unit pixel G1. Thus, the second isolation pattern 130 may not only prevent or reduce optical crosstalk between the first unit pixel G1 and the fourth unit pixel G4, but also improve the light condensing efficiency of the first unit pixel G1. When the second isolation pattern 130 is not present, the light incident obliquely on the second surface 100b of the first unit pixel G1 may pass through the first unit pixel G1 to the fourth unit pixel G4, as shown by a second optical path LP2 in FIG. 7. This may cause optical crosstalk between the first unit pixel G1 and the fourth unit pixel G4.

Furthermore, the second isolation pattern 130 may extend from the second surface 100b and may be spaced apart from the first surface 100a. Accordingly, even though the second isolation pattern 130 is positioned in the center area of the adjacent unit pixels in which the first isolation pattern 120 is absent, the second isolation pattern 130 may provide an effective space in the center area of the adjacent unit pixels. For example, as described above, at least a portion of the floating diffusion area FD may be positioned at the center of the first to fourth unit pixels G1 to G4 so as to overlap the second isolation pattern 130 in the third direction Z. This floating diffusion area FD may be shared with adjacent unit pixels, thereby reducing an area size of each of the unit pixels and thus contributing to high integration of the image sensor. Thus, an image sensor with improved performance and integration may be provided.

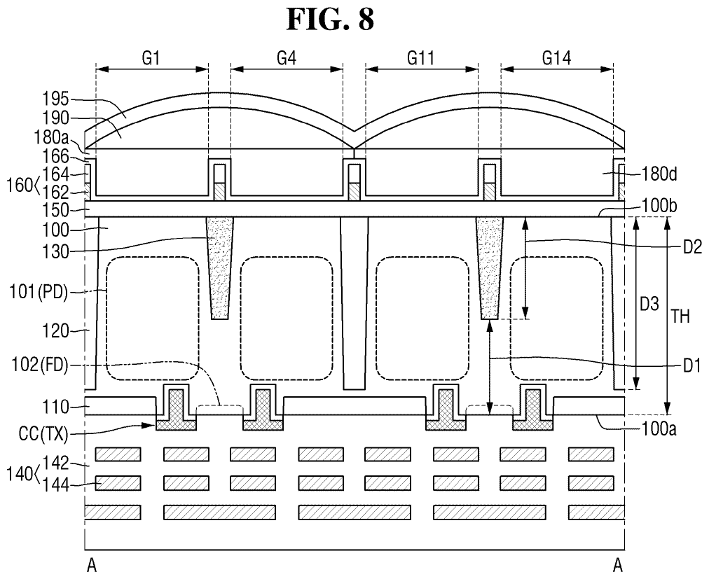

FIG. 8 to FIG. 10 are cross-sectional views for illustrating an image sensor according to some example embodiments. For convenience of description, contents duplicate with those as described above with reference to FIG. 1 to FIG. 7 are briefly described or omitted.

Referring to FIG. 8 to FIG. 10, in the image sensor according to some example embodiments, the first isolation pattern 120 may extend from the second surface 100b of the first substrate 100.

The width of the first isolation pattern 120 may decrease as the first isolation pattern 120 extends from the second surface 100b to the first surface 100a. For example, the first isolation pattern 120 may be formed by filling an insulating material in a deep trench formed by patterning a portion of the first substrate 100 including the second surface 100b. For example, a depth D3 of the first isolation pattern 120 from the second surface 100b of the first substrate 100 may be about or exactly 2 μm or larger (such as up to about or exactly 10 μm).

The first isolation pattern 120 may include an insulating material, for example, at least one of silicon oxide, silicon nitride, silicon oxynitride, and combinations thereof. However, the present disclosure is not limited thereto. The first isolation pattern 120 may include the same insulating material as that of the second isolation pattern 130, or may include a different insulating material from that of the second isolation pattern 130.

In some example embodiments, the first isolation pattern 120 may include a low refractive index material having a lower refractive index than a refractive index of silicon (Si), for example, at least one of silicon oxide, aluminum oxide, tantalum oxide, and combinations thereof. The first isolation pattern 120 may refract or reflect light incident at an angle to the second surface 100b as a light-receiving surface, thereby improving light condensing efficiency.

In some example embodiments, the first isolation pattern 120 may not extend through an entirety of the first substrate 100. For example, the first isolation pattern 120 may be spaced from the first surface 100a of the first substrate 100. In some example embodiments, the first isolation pattern 120 may be spaced from the element isolation film 110 in the third direction Z.

In some example embodiments, the depth D2 by which the second isolation pattern 130 is formed may be smaller than the depth D3 by which the first isolation pattern 120 is formed.

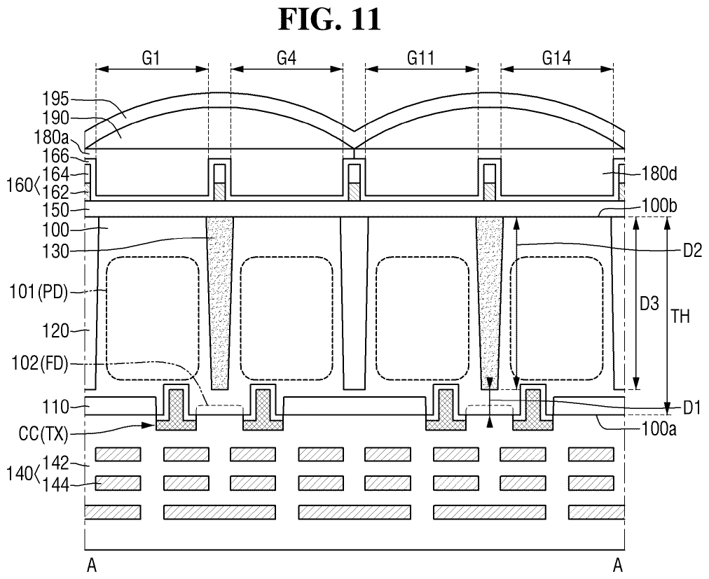

FIG. 11 is a cross-sectional view for illustrating an image sensor according to some example embodiments. For convenience of description, contents duplicate with those as described above with reference to FIG. 1 to FIG. 10 are briefly described or omitted.

Referring to FIG. 11, in the image sensor according to some example embodiments, the depth D2 by which the second isolation pattern 130 is formed may be the same as the depth D3 by which the first isolation pattern 120 is formed. As used herein, the terms “same” means not only “being exactly equal to” but also including a minor difference that may occur due to process margins, etc.

In some example embodiments, the first isolation pattern 120 may include a different insulating material than that of the second isolation pattern 130. For example, the first isolation pattern 120 and the second isolation pattern 130 may be formed in different manufacturing processes.

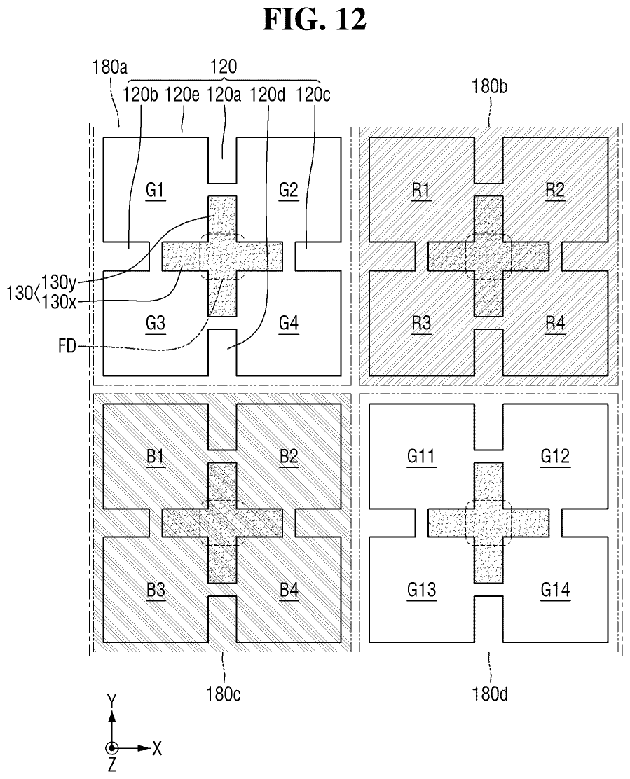

FIG. 12 to FIG. 14 are various layout diagrams for illustrating an image sensor according to some example embodiments. For convenience of description, contents duplicate with those as described above with reference to FIG. 1 to FIG. 11 are briefly described or omitted.

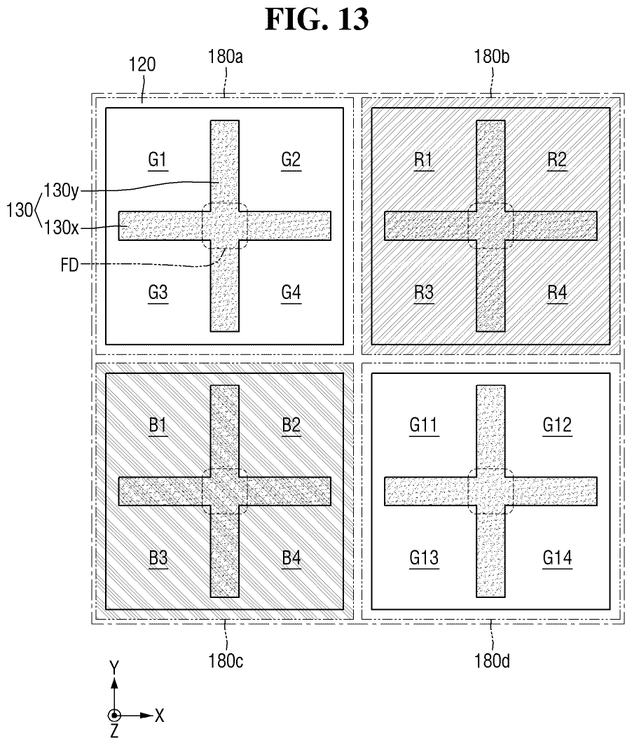

Referring to FIG. 12 and FIG. 13, in the image sensor according to some example embodiments, the second isolation pattern 130 may include a first extension 130y and a second extension 130x intersecting each other.

For example, the first extension 130y may extend in the second direction Y, and the second extension 130x may extend in the first direction X. Each of the first extension 130y and the second extension 130x may be interposed between adjacent unit pixels. In some example embodiments, the first extension 130y may be interposed between the first unit pixel G1 and the second unit pixel G2 and between the third unit pixel G3 and the fourth unit pixel G4. In some example embodiments, the second extension 130x may be interposed between the first unit pixel G1 and third unit pixel G3 and between the second unit pixel G2 and fourth unit pixel G4. The second isolation pattern 130 along with the first isolation pattern 120 may surround each of the unit pixels G1 to G4, R1 to R4, B1 to B4, and G11 to G14.

In some example embodiments, as shown in FIG. 12, the first extension 130y and the second extension 130x may be interposed between the first to fourth pixel isolation portions 120a to 120d. For example, the first extension 130y may be interposed between the first pixel isolation portion 120a and the fourth pixel isolation portion 120d. The first pixel isolation portion 120a, the first extension 130y, and the fourth pixel isolation portion 120d may be arranged in a line in the second direction Y. The second extension 130x may be interposed between the second pixel isolation portion 120b and the third pixel isolation portion 120c. The second pixel isolation portion 120b, the second extension 130x, and the third pixel isolation portion 120c may be arranged in a line in the first direction X.

In some example embodiments, as shown in FIG. 13, the second isolation pattern 130 may isolate adjacent ones of the unit pixels G1 to G4, R1 to R4, B1 to B4, and G11 to G14 from each other while being disposed inwardly of the first isolation pattern 120. For example, the first isolation pattern 120 may not include the first to fourth pixel isolation portion 120a to 120d as described above.

In some example embodiments, the second extension 130x and the first extension 130y may cross each other overlapping the floating diffusion area FD.

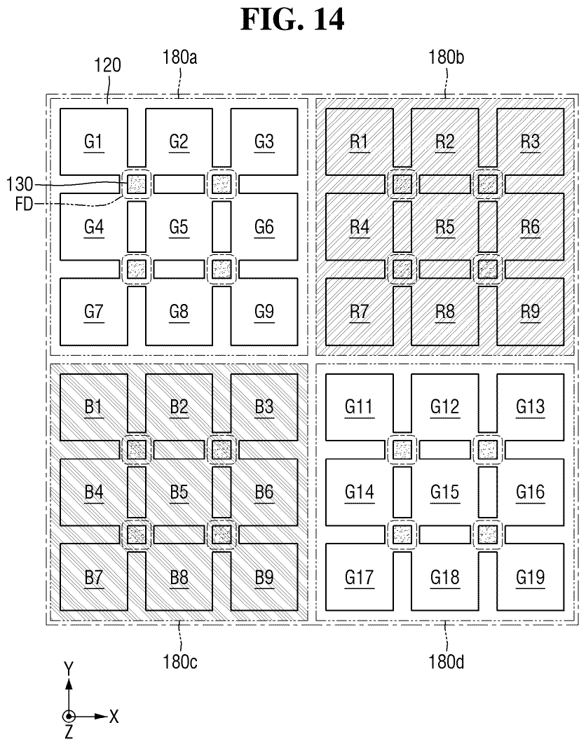

Referring to FIG. 14, in an image sensor according to some example embodiments, each pixel group may include 9 unit pixels.

For example, each of a first pixel group G1 to G9, a second pixel group R1 to R9, a third pixel group B1 to B9, and a fourth pixel group G11 to G19 may include the 9 unit pixels arranged in a 3x3 matrix.

The second isolation pattern 130 may be positioned in each pixel group. In some example embodiments, the second isolation pattern 130 may be interposed between unit pixels adjacent to each other in the diagonal direction. In some example embodiments, the second isolation pattern 130 disposed in the first pixel group G1 to G9 may include the second isolation pattern 130 disposed between the first unit pixel G1 and the 13th unit pixel G5, the second isolation pattern 130 disposed between the second unit pixel G2 and the 14th unit pixel G6, the second isolation pattern 130 disposed between the fourth unit pixel G4 and the 15th unit pixel G8, and the second isolation pattern 130 disposed between the 13th unit pixel G5 and the 16th unit pixel G9.

Although the description has been made mainly based on some example embodiments in which the unit pixels are arranged in a 3×3 matrix form, this is only an example and the inventive concepts are not limited thereto. Those skilled in the art in the technical field to which the present disclosure belongs will understand that the second isolation pattern 130 may be applied to a 2×3 matrix form, a 3×4 matrix form, and/or a 4×4 matrix under the same principle.

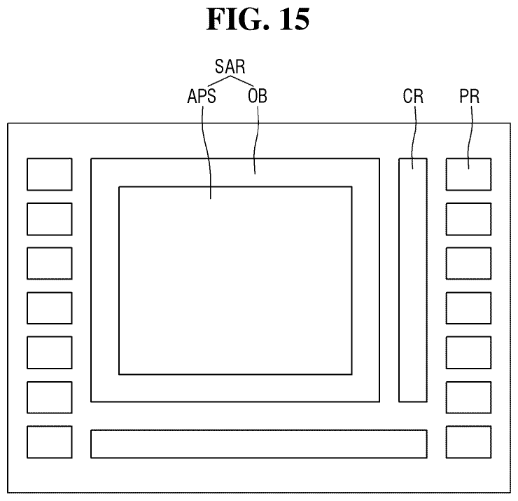

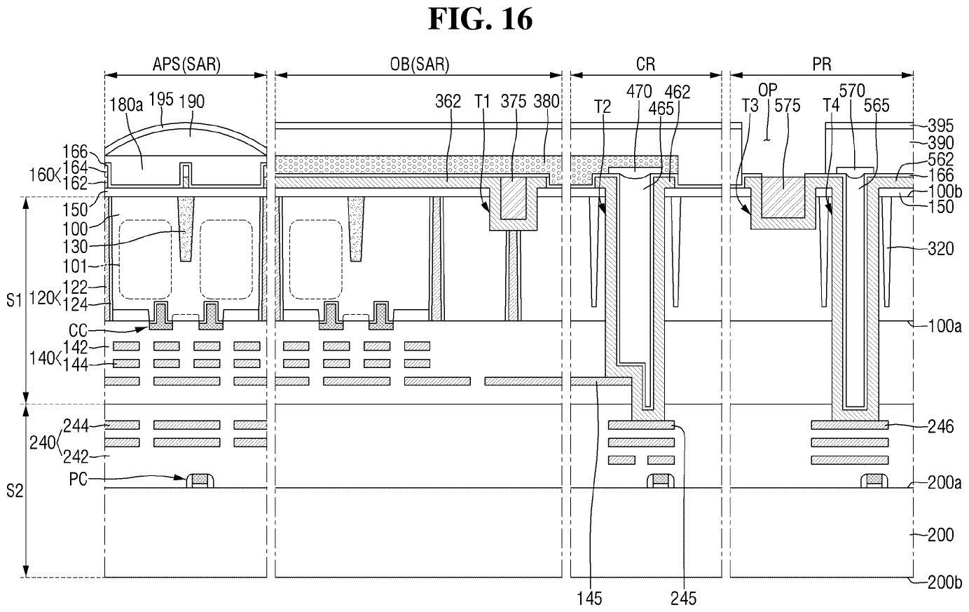

FIG. 15 is a schematic layout diagram for illustrating an image sensor according to some example embodiments. FIG. 16 is a schematic cross-sectional view for illustrating the image sensor in FIG. 15. For convenience of description, contents duplicate with those as described above with reference to FIG. 1 to FIG. 14 are briefly described or omitted.

Referring to FIG. 15 and FIG. 16, an image sensor according to some example embodiments includes a sensor array area SAR, a connection area CR, and a pad area PR.

The sensor array area SAR may include an area corresponding to the active pixel sensor array 1 in FIG. 1. For example, in the sensor array area SAR, the plurality of unit pixels arranged two-dimensionally, for example, in a matrix form may be formed.

The sensor array area SAR may include a light receiving area APS and a light blocking area OB. Active pixels that receive light and generate an active signal based on the received light may be arranged in the light receiving area APS. In the light blocking area OB, optical black pixels that block light to generate an optical black signal may be arranged. For example, the light blocking area OB may be formed around the light receiving area APS. However, this is only an example and the inventive concepts are not limited thereto.

In some example embodiments, the photoelectric conversion area 101 may be formed in one portion of the light blocking area OB and may not be formed in the other portion of the light blocking area OB. For example, the photoelectric conversion area 101 may be formed in one portion of the light-shielding area OB adjacent to the light-receiving area APS, but may not be formed in the other portion of the light-shielding area OB that is spaced from the light-receiving area APS.

In some example embodiments, dummy pixels (not shown) may be formed in a portion of the light receiving area APS adjacent to the light blocking area OB.

The connection area CR may be formed around the sensor array area SAR. The connection area CR may be formed on one side of the sensor array area SAR. However, this is only an example and the inventive concepts are not limited thereto. Wirings may be formed in the connection area CR and may transmit and receive an electrical signal of the sensor array area SAR.

The pad area PR may be formed around the sensor array area SAR. The pad area PR may be formed adjacent to an edge of the image sensor according to some example embodiments. However, this is only an example and the inventive concepts are not limited thereto. The pad area PR may be connected to an external device, etc., and may be configured to communicate the electrical signal between the image sensor according to some example embodiments and the external device.

The connection area CR is shown as being interposed between the sensor array area SAR and the pad area PR. However, this is only illustrative. An arrangement of the sensor array area SAR, the connection area CR, and the pad area PR may vary as needed.

The first wiring structure 140 may include the first wiring pattern 144 in the sensor array area SAR and a second wiring pattern 145 in the connection area CR. The first wiring pattern 144 may be electrically connected to the unit pixels of the sensor array area SAR. At least a portion of the second wiring pattern 145 may be electrically connected to at least a portion of the first wiring pattern 144. Thus, the second wiring pattern 145 may be electrically connected to the unit pixels of the sensor array area SAR.

The image sensor according to some example embodiments may include a second substrate 200 and a second wiring structure 240.

The second substrate 200 may be made of bulk silicon or (SOI) silicon-on-insulator. The second substrate 200 may be a silicon substrate, or may include a material other than silicon, such as silicon germanium, indium antimonide, lead telluride compound, indium arsenide, indium phosphide, gallium arsenide, or gallium antimonide. Alternatively, the second substrate 200 may have a base substrate and an epitaxial layer formed on the base substrate.

The second substrate 200 may include a third surface 200a and a fourth surface 200b that are opposite to each other. In some example embodiments as described later, the third surface 200a may also be referred to as a front surface of the second substrate 200, and the fourth surface 200b may also be referred to as a rear or back surface of the second substrate 200. In some example embodiments, the third surface 200a of the second substrate 200 may face the first surface 100a of the first substrate 100.

A second circuit element PC may be formed on the third surface 200a of the second substrate 200. The second circuit element PC may be electrically connected to the sensor array area SAR and may transmit and receive electrical signals to and from each unit pixel of the sensor array area SAR. For example, the second circuit element PC may include the electronic elements that constitute the row decoder 2, the row driver 3, the column decoder 4, the timing generator 5, the correlated double sampler 6, the analog-to-digital converter 7, or the input/output buffer 8 in FIG. 1.

The second wiring structure 240 may be formed on the third surface 200a of the second substrate 200. For example, the second wiring structure 240 may include a second inter-wiring insulating film 242 and various wiring patterns 244, 245, and 246 disposed in the second inter-wiring insulating film 242.

In FIG. 16, the number of layers and the arrangement of wiring patterns 244, 245, and 246 are illustrative only and are not limited thereto.

At least some of the wiring patterns 244, 245, and 246 of the second wiring structure 240 may be connected to the second circuit element PC. In some example embodiments, the second wiring structure 240 may include a third wiring pattern 244 in the sensor array area SAR, a fourth wiring pattern 245 in the connection area CR, and a fifth wiring pattern 246 in the pad area PR. In some example embodiments, the fourth wiring pattern 245 may be a top wiring among a plurality of wirings in the connection area CR, and the fifth wiring pattern 246 may be a top wiring among a plurality of wirings in the pad area PR.

The first wiring structure 140 and the second wiring structure 240 may be bonded to each other. For example, as shown in FIG. 16, an upper surface of the second wiring structure 240 may be attached to a lower surface of the first wiring structure 140. The first wiring structure 140 and the second wiring structure 240 may be bonded to each other via, for example, a wafer bonding process. However, the present disclosure is not limited thereto.

The image sensor according to some example embodiments may include a first connection structure 362, a second connection structure 462, and a third connection structure 562.

The first connection structure 362 may be formed in the light blocking area OB. The first connection structure 362 may be formed on the surface insulating film 150 and in the light blocking area OB. The first connection structure 362 may contact a portion of the first isolation pattern 120. For example, a first trench Tl exposing the first isolation pattern 120 may be formed in the first substrate 100 and the surface insulating film 150 and in the light blocking area OB. The first connection structure 362 may be formed in the first trench T1 so as to contact the first isolation pattern 120 in the light blocking area OB. In some example embodiments, the first connection structure 362 may extend conformally along a profile of each of a side surface and a lower surface of the first trench T1.

The first connection structure 362 may include, but is limited to, at least one of, for example, titanium (Ti), titanium nitride (TiN), tantalum (Ta), tantalum nitride (TaN), tungsten (W), aluminum (Al), copper (Cu), and combinations thereof.

In some example embodiments, the first connection structure 362 may be electrically connected to the filling pattern 122 of the first isolation pattern 120 and may apply a ground voltage or a negative voltage to the filling pattern 122. Accordingly, charges generated under ESD, etc. may be discharged to the first connection structure 362 through the filling pattern 122. Thus, ESD bruising defects may be effectively prevented or reduced.

In some example embodiments, a first pad 375 filling the first trench T1 may be formed on the first connection structure 362. The first pad 375 may include, but is not limited to, at least one of, for example, tungsten (W), copper (Cu), aluminum (Al), gold (Au), silver (Ag), and alloys thereof.

In some example embodiments, the first protective film 166 may cover the first connection structure 362 and the first pad 375. For example, the first protective film 166 may extend conformally along a profile of each of the first connection structure 362 and the first pad 375.

The second connection structure 462 may be formed in the connection area CR. The second connection structure 462 may be formed on the surface insulating film 150 and in the connection area CR. The second connection structure 462 may electrically connect the first wiring structure 140 and the second wiring structure 240 to each other. For example, in the connection area CR, a second trench T2 may be formed so as to expose the second wiring pattern 145 and the fourth wiring pattern 245. The second connection structure 462 may be formed in the second trench T2 so as to connect the second wiring pattern 145 and the fourth wiring pattern 245 to each other. In some example embodiments, the second connection structure 462 may extend conformally along a profile of each of a side surface and a lower surface of the second trench T2.

The second connection structure 462 may include, but is limited to, at least one of, for example, titanium (Ti), titanium nitride (TiN), tantalum (Ta), tantalum nitride (TaN), tungsten (W), aluminum (Al), copper (Cu), and combinations thereof. In some example embodiments, the second connection structure 462 may be positioned at the same vertical level as that of the first connection structure 362.

In some example embodiments, the first protective film 166 may cover the second connection structure 462. For example, the first protective film 166 may extend along a profile of the second connection structure 462.

In some example embodiments, a first filling insulating film 465 may be formed on the second connection structure 462 so as to fill the second trench T2. The first filling insulating film 465 may include, but is not limited to, at least one of, for example, silicon oxide, aluminum oxide, tantalum oxide, and combinations thereof.

In some example embodiments, a first capping pattern 470 may be formed on the first filling insulating film 465. The first capping pattern 470 may cover an upper surface of the first filling insulating film 465.

The third connection structure 562 may be formed in the pad area PR. The third connection structure 562 may be formed on the surface insulating film 150 and in the pad area PR. The third connection structure 562 may electrically connect the second wiring structure 240 and an external device to each other. For example, in the first substrate 100 and in the pad area PR, a third trench T3 may be formed. The third connection structure 562 may be formed in the third trench T3 so as to be exposed. Furthermore, in the pad area PR, a fourth trench T4 may be formed so as to expose the fifth wiring pattern 246. The third connection structure 562 may be formed in the fourth trench T4 so as to contact the fifth wiring pattern 246. In some example embodiments, the third connection structure 562 may extend conformally along a profile of each of a side surface and a lower surface of each of the third trench T3 and the fourth trench T4.

The third connection structure 562 may include, for example, at least one of titanium (Ti), titanium nitride (TiN), tantalum (Ta), tantalum nitride (TaN), tungsten (W), aluminum (Al), copper (Cu), and combinations thereof. However, the present disclosure is not limited thereto. In some example embodiments, the third connection structure 562 may be positioned at the same vertical level as that of each of the first connection structure 362 and the second connection structure 462.

In some example embodiments, a second filling insulating film 560 may be formed on the third connection structure 562 so as to fill the fourth trench T4. The second filling insulating film 560 may include, but is not limited to, at least one of, for example, silicon oxide, aluminum oxide, tantalum oxide, and combinations thereof. In some example embodiments, the second filling insulating film 560 may be positioned at the same vertical level as that of the first filling insulating film 465.

In some example embodiments, a second pad 575 may be formed on the third connection structure 562 so as to fill the fourth trench T4. The second pad 575 may include, but is not limited to, at least one of, for example, tungsten (W), copper (Cu), aluminum (Al), gold (Au), silver (Ag), and alloys thereof. In some example embodiments, the second pad 575 may be positioned at the same vertical level as that of the first pad 375.

In some example embodiments, the first protective film 166 may cover the third connection structure 562. For example, the first protective film 166 may extend conformally along a profile of the third connection structure 562. In some example embodiments, the first protective film 166 may not cover the second pad 575 so as to be exposed.

In some example embodiments, a third isolation pattern 320 may be formed in the first substrate 100. The third isolation pattern 320 is shown to be formed only around the second connection structure 462 and around the third connection structure 562, but this is only an example and the inventive concepts are not limited thereto. For example, the third isolation pattern 320 may be further formed around the first connection structure 362. The third isolation pattern 320 may include, but is not limited to, at least one of, for example, silicon oxide, silicon nitride, silicon oxynitride, aluminum oxide, hafnium oxide, and combinations thereof.

In some example embodiments, a width of the third isolation pattern 320 may decrease as the third isolation pattern 320 extends from the second surface 100b of the first substrate 100 toward the first surface 100a of the first substrate 100. This may be due to the characteristics of an etching process to form the third isolation pattern 320. For example, the third isolation pattern 320 may be embodied as BDT1 (backside deep trench isolation) formed by a DT1 (deep trench isolation) process performed on the second surface 100b of the first substrate 100. In some example embodiments, the third isolation pattern 320 may be spaced apart from the first surface 100a of the first substrate 100.

In some example embodiments, a light blocking color filter 380 may be formed on the first connection structure 362 and the second connection structure 462. For example, the light blocking color filter 380 may be formed to cover at least a portion of the first protective film 166 in the light blocking area OB and the connection area CR. The light blocking color filter 380 may prevent or reduce light from being incident on the first substrate 100.

In some example embodiments, the third protective film 390 may be formed on the light blocking color filter 380. For example, the third protective film 390 may be formed to cover at least a portion of the first protective film 166 in the light blocking area OB, the connection area CR, and the pad area PR. In some example embodiments, the second protective film 195 may extend along a surface of the third protective film 390. The third protective film 390 may include, for example, a light-transmissive resin. However, the present disclosure is not limited thereto. In some example embodiments, the third protective film 390 may be positioned at the same vertical level as that of the micro lens 190.

In some example embodiments, the second protective film 195 and the third protective film 390 may not cover the second pad 575 so as to be exposed. For example, an exposure opening OP exposing the second pad 575 may be formed in the second protective film 195 and the third protective film 390. Accordingly, the second pad 575 may be connected to an external device, etc., and may be configured to communicate electrical signals between the image sensor according to some example embodiments and the external device. That is, the second pad 575 may act as an input/output pad of the image sensor according to some example embodiments.

Hereinafter, with reference to FIG. 1 to FIG. 24, a method for manufacturing an image sensor according to some example embodiments is described.

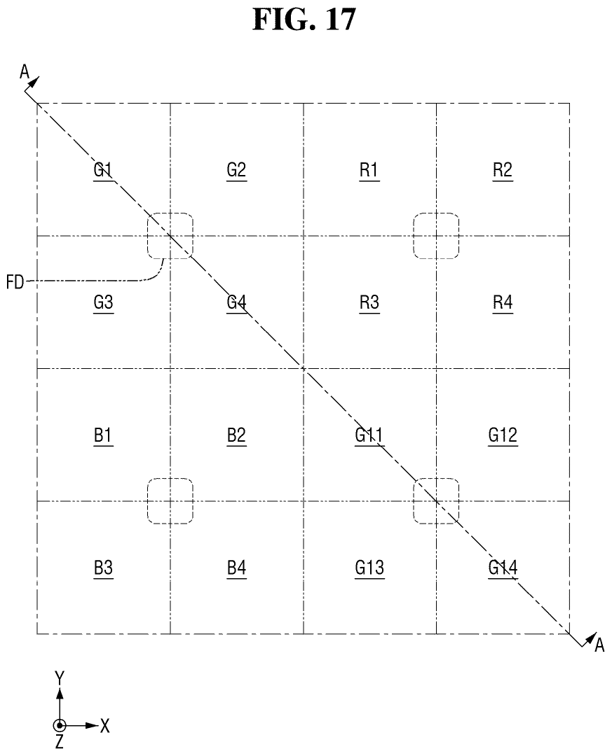

FIG. 17 to FIG. 24 are drawings of intermediate structures corresponding to intermediate steps of the manufacturing method of the image sensor according to some example embodiments. For convenience of description, contents duplicate with those as described above with reference to FIG. 1 to FIG. 16 is briefly described or omitted.

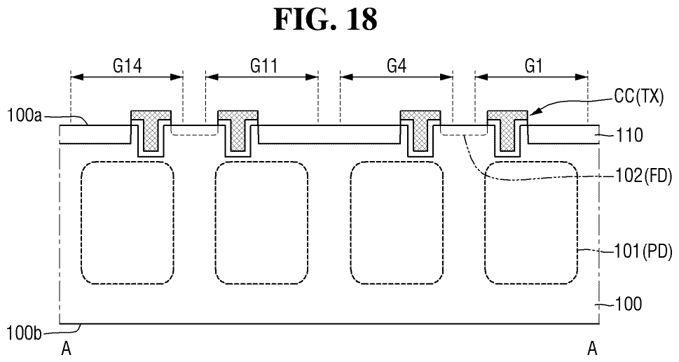

Referring to FIG. 17 and FIG. 18, the photoelectric conversion area 101, the element isolation film 110, and the active area 102 are formed in the first substrate 100. Subsequently, the first circuit element CC is formed on the first substrate 100.

For example, the photoelectric conversion area 101 may be formed by ion implanting n-type impurities into the first substrate 100 of the p-type. The photoelectric conversion area 101 may be formed in each of the unit pixels G1 to G4, R1 to R4, B1 to B4, and G11 to G14 arranged in the first substrate 100.

The element isolation film 110 may define the active area 102 in each of the unit pixels G1 to G4, R1 to R4, B1 to B4, and G11 to G14. The element isolation film 110 may extend on and along the first surface 100a of the first substrate 100, and may define the active area 102 extending from the first surface 100a in the first substrate 100. For example, the element isolation film 110 may be formed by an ST1 shallow trench isolation process on the first surface 100a of the first substrate 100.

The active area 102 may include the floating diffusion area FD. For example, the floating diffusion area FD may be formed by ion implanting n-type impurities into the first substrate 100 of the p-type. In some example embodiments, the floating diffusion area FD may be interposed between unit pixels adjacent to each other in the diagonal direction. In some example embodiments, the floating diffusion area FD of the first pixel group G1 to G4 may be interposed between the first unit pixel G1 and fourth unit pixel G4 and/or between the second unit pixel G2 and third unit pixel G3.

The first circuit element CC may be formed on the first surface 100a of the first substrate 100. The first circuit element CC may include various transistors for processing the electrical signal generated from each of the unit pixels G1 to G4, R1 to R4, B1 to B4, and G11 to G14 in the first substrate 100. For example, the first circuit element CC may include the transfer transistor TX, the reset transistor RX, the drive transistor DX, and/or the select transistor SX, etc. as described above in the description of FIG. 2.

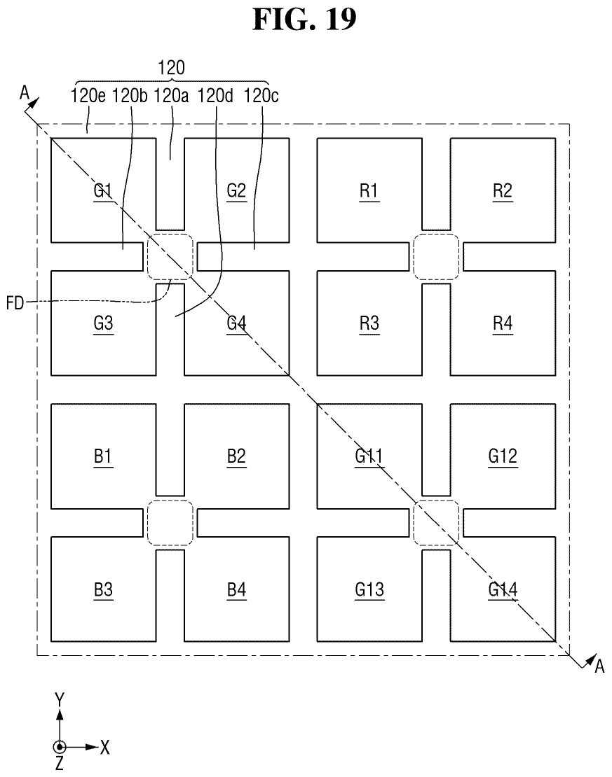

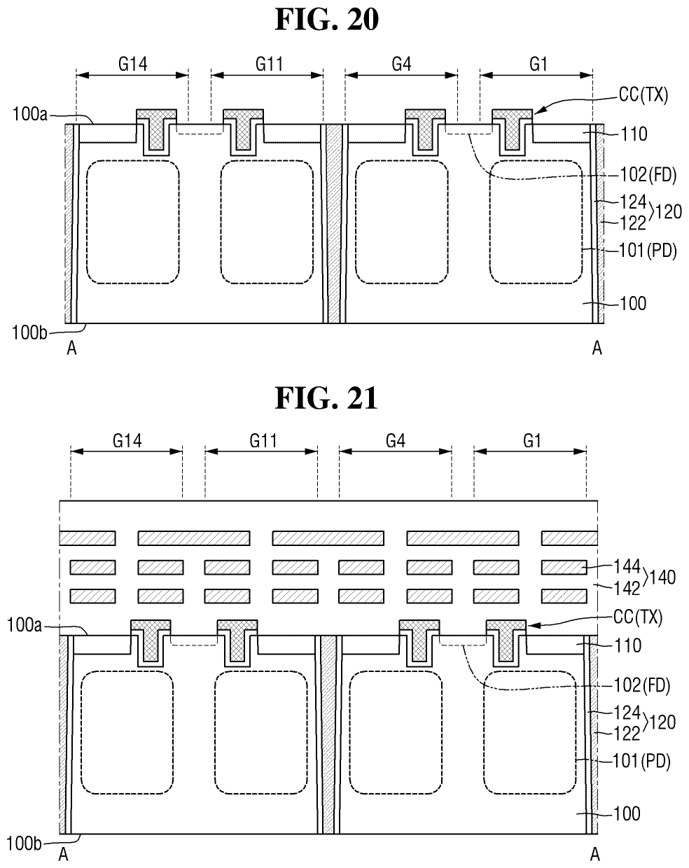

Referring to FIG. 19 and FIG. 20, the first isolation pattern 120 is formed in the first substrate 100.

For example, the first isolation pattern 120 may be formed by burying an insulating material in a deep trench formed by patterning a portion of the first substrate 100 including the first surface 100a. In some example embodiments, the first isolation pattern 120 may include the filling pattern 122 and the spacer film 124.

The first isolation pattern 120 may define the plurality of pixel groups in the first substrate 100. For example, the first isolation pattern 120 may surround each of the first pixel group G1 to G4, the second pixel group R1 to R4, the third pixel group B1 to B4, and the fourth pixel group G11 to G14 in a plan view.

In some example embodiments, the first isolation pattern 120 may be absent in the center of adjacent unit pixels of each pixel group. For example, the first isolation pattern 120 may include the group isolation portion 120e and the first to fourth pixel isolation portions 120a to 120d.

Referring to FIG. 21, the first wiring structure 140 is formed on the first substrate 100.

The first wiring structure 140 may be formed on the first surface 100a of the first substrate 100. The first wiring structure 140 may include the first inter-wiring insulating film 142 on the first surface 100a and the first wiring pattern 144 disposed in the first inter-wiring insulating film 142. The first wiring structure 140 may be electrically connected to the first circuit element CC and may communicate the electrical signal with each of the unit pixels G1 to G4, R1 to R4, B1 to B4, and G11 to G14 via the first circuit element CC.

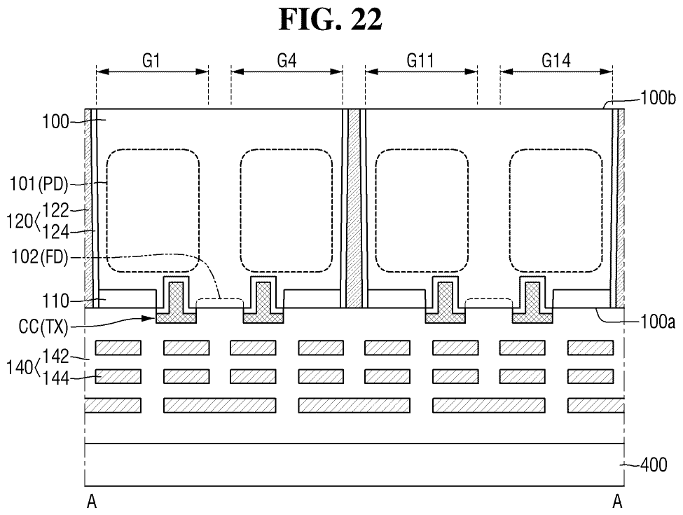

Referring to FIG. 22, the first wiring structure 140 is attached on a carrier substrate 400.

For example, the carrier substrate 400 may be attached to a resulting structure of FIG. 21. After the carrier substrate 400 is attached thereto, the resulting structure of FIG. 21 may be turned upside down. For example, as shown, the second surface 100b of the first substrate 100 may face upwardly. In some example embodiments, the first wiring structure 140 may be attached to the carrier substrate 400 in an oxide-oxide bonding process.

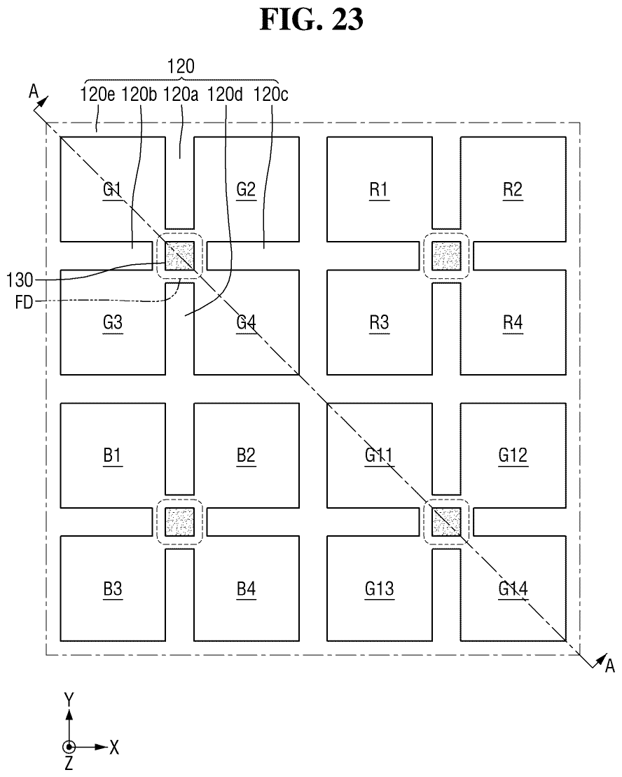

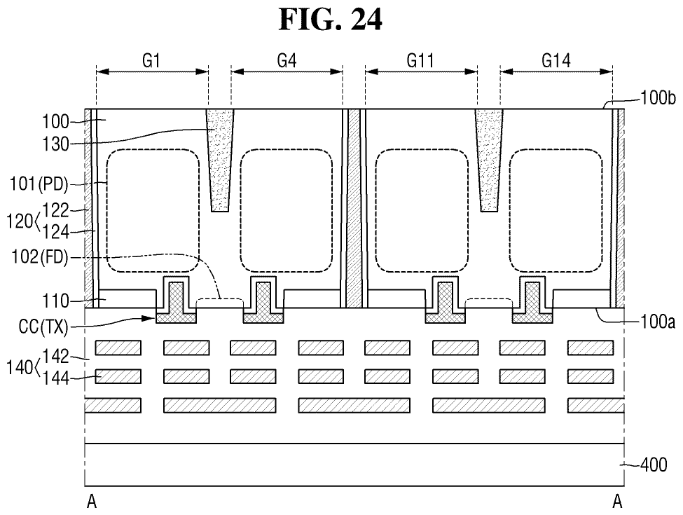

Referring to FIG. 23 and FIG. 24, the second isolation pattern 130 is formed in the first substrate 100.

For example, the second isolation pattern 130 may be formed by burying an insulating material in a deep trench formed by patterning a portion of the first substrate 100 including the second surface 100b.

The second isolation pattern 130 may be interposed between unit pixels adjacent to each other in the diagonal direction. In some example embodiments, the second isolation pattern 130 of the first pixel group G1 to G4 may be interposed between the first unit pixel G1 and fourth unit pixel G4 and/or between the second unit pixel G2 and third unit pixel G3.

Next, referring to FIG. 3 and FIG. 4, the surface insulating film 150, the grid pattern 160, the first protective film 166, the color filters 180a to 180d, and the micro lens 190 are formed on the second surface 100b of the first substrate 100. Thus, the image sensor as described above using FIG. 3 to FIG. 7 may be manufactured.

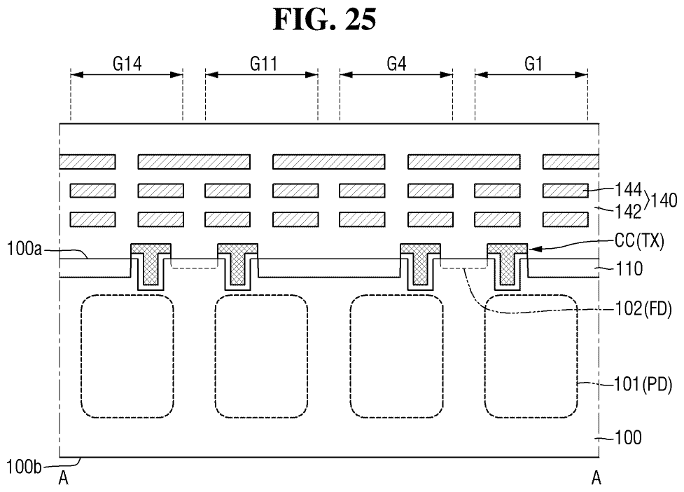

FIG. 25 to FIG. 30 are drawings of intermediate structures corresponding to intermediate steps of a method for manufacturing an image sensor according to some example embodiments. For reference, FIG. 25 is a drawing of an intermediate structure corresponding to a step following FIG. 18.

Referring to FIG. 25, the first wiring structure 140 is formed on the first substrate 100. Since forming the first wiring structure 140 is similar to what has been described above using FIG. 21, detailed description thereof is omitted below.

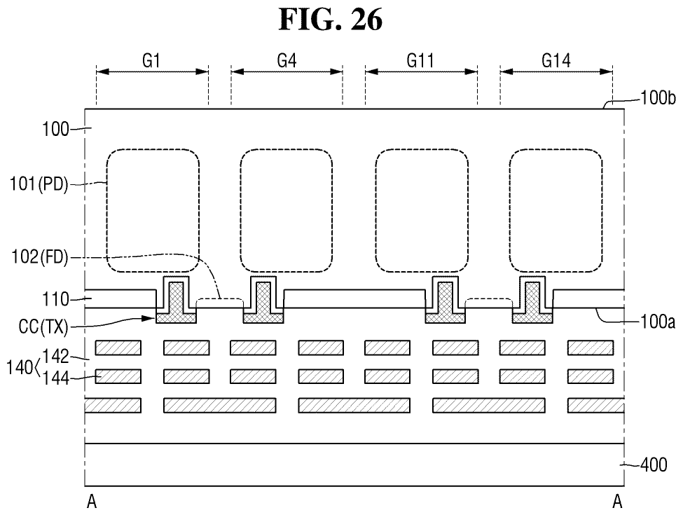

Referring to FIG. 26, the first wiring structure 140 is attached to the carrier substrate 400. Attaching the first wiring structure 140 thereto is similar to what has been described above using FIG. 22. Thus, detailed description thereof is omitted below.

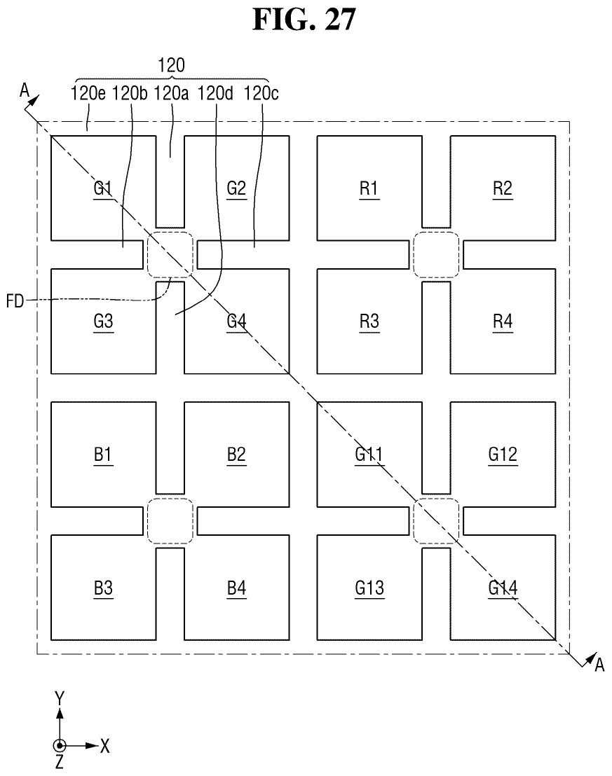

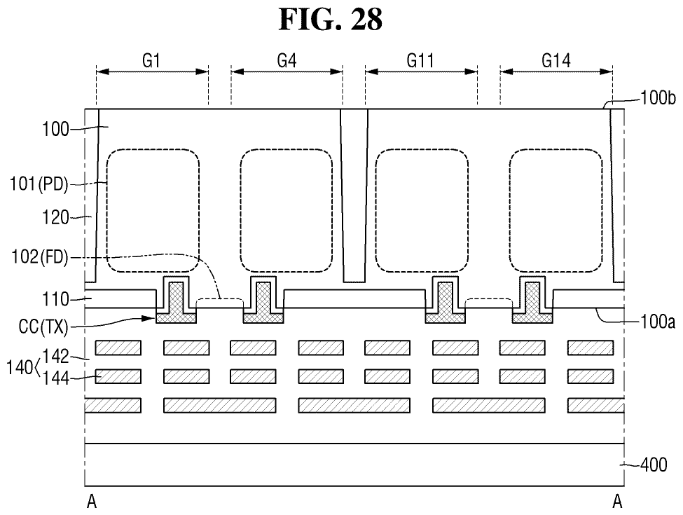

Referring to FIG. 27 and FIG. 28, the first isolation pattern 120 is formed in the first substrate 100.

For example, the first isolation pattern 120 may be formed by burying an insulating material in a deep trench formed by patterning a portion of the first substrate 100 including the second surface 100b.

The first isolation pattern 120 may define the plurality of pixel groups in the first substrate 100. For example, the first isolation pattern 120 may surround each of the first pixel group G1 to G4, the second pixel group R1 to R4, the third pixel group B1 to B4, and the fourth pixel group G11 to G14 in a plan view.

In some example embodiments, the first isolation pattern 120 may be absent in the center of adjacent unit pixels of each pixel group. For example, the first isolation pattern 120 may include the group isolation portion 120e and the first to fourth pixel isolation portions 120a to 120d.

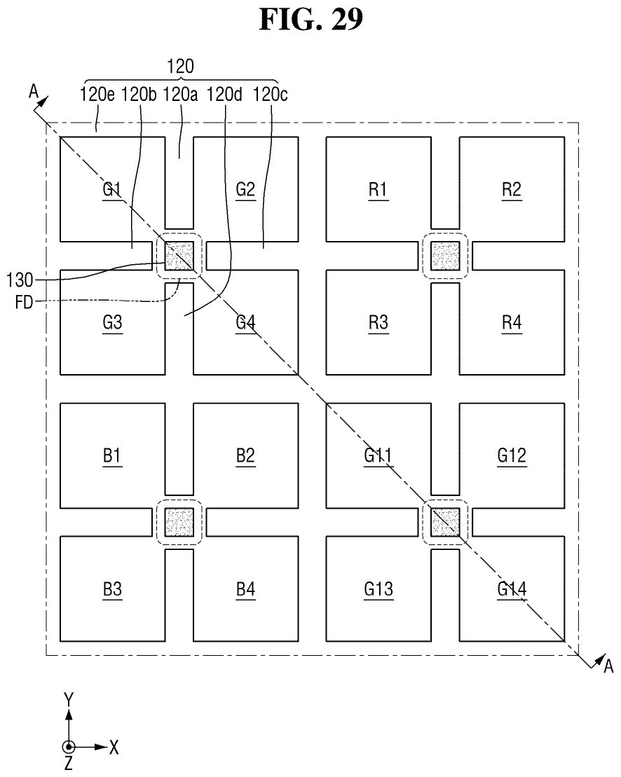

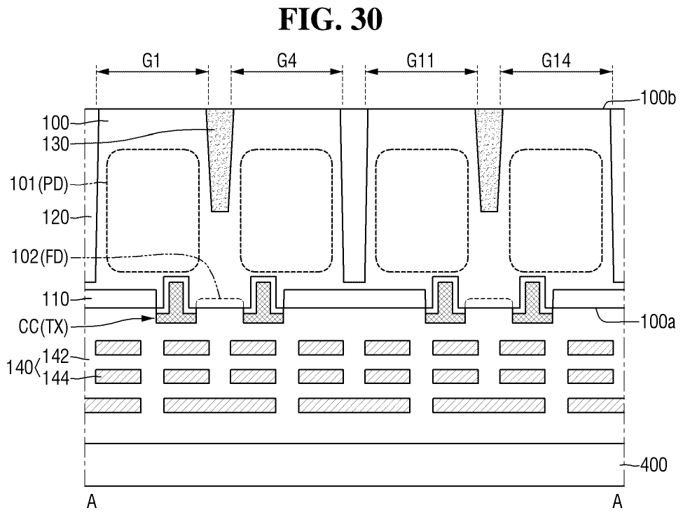

Referring to FIG. 29 and FIG. 30, the second isolation pattern 130 is formed in the first substrate 100. Forming the second isolation pattern 130 is similar to what has been described above using FIG. 23 and FIG. 24. Thus, detailed description thereof is omitted below.

Next, referring to FIG. 8, the surface insulating film 150, the grid pattern 160, the first protective film 166, the color filters 180a to 180d, and the micro lens 190 are formed on the second surface 100b of the first substrate 100. Thus, the image sensor as described above using FIG. 8 to FIG. 10 may be manufactured.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Although the example embodiments of the present disclosure have been described above with reference to the accompanying drawings, the present disclosure may not be limited to the example embodiments and may be implemented in various different forms. Those of ordinary skill in the technical field to which the present disclosure belongs will be able to appreciate that the present disclosure may be implemented in other specific forms without changing the technical ideas or essential features of the present disclosure. Therefore, it should be understood that the example embodiments as described above are not restrictive but illustrative in all respects.

What is claimed is:

1. An image sensor comprising:
a substrate including a first surface and a second surface opposed to each other;
a first pixel group in the substrate, the first pixel group including
a first unit pixel,
a second unit pixel adjacent to the first unit pixel in a first direction in a plan view,
a third unit pixel adjacent to the first unit pixel in a second direction perpendicular to the first direction in the plan view, and
a fourth unit pixel adjacent to the second unit pixel in the second direction in the plan view and adjacent to the third unit pixel in the first direction in the plan view;
a photoelectric conversion area in each of the first to fourth unit pixels;
a first isolation trench in the substrate, the first isolation trench surrounding the first pixel group;
a second isolation trench in the substrate, the second isolation trench between the first unit pixel and the fourth unit pixel and between the second unit pixel and the third unit pixel, wherein the second isolation trench is in contact with the second surface of the substrate; and
a first color filter on the second surface of the substrate, the first color filter covering the first pixel group.

2. The image sensor of claim 1, wherein the first isolation trench includes:
a first pixel isolation trench between the first unit pixel and the third unit pixel, wherein the first pixel isolation trench extends in the first direction; and
a second pixel isolation trench between the second unit pixel and the fourth unit pixel, wherein the second pixel isolation trench extends in the first direction,
wherein the second isolation trench is between the first and second pixel isolation trenches and spaced apart from the first and second pixel isolation trenches.

3. The image sensor of claim 2, wherein a depth of the first pixel isolation trench from the second surface of the substrate in a third direction perpendicular to the first and second directions is greater than a depth of the second isolation trench from the second surface of the substrate in the third direction.

4. The image sensor of claim 3, wherein the first pixel isolation trench is in contact with the first and second surfaces of the substrate.

5. The image sensor of claim 4, further comprising a floating diffusion area on the first surface of the substrate,
wherein at least a portion of the floating diffusion area is vertically overlapped with the second isolation trench in the third direction.

6. The image sensor of claim 4, wherein the first pixel isolation trench includes a silicon oxide layer and an aluminum oxide layer.

7. The image sensor of claim 4, wherein the second isolation trench includes a low refractive index material having a lower refractive index than a refractive index of silicon (Si).

8. The image sensor of claim 7, wherein the low refractive index material includes at least one of silicon oxide, aluminum oxide, tantalum oxide, and combinations thereof.

9. The image sensor of claim 4, further comprising:
a second pixel group adjacent to the first pixel group in the substrate, the second pixel group including
a fifth unit pixel,
a sixth unit pixel adjacent to the fifth unit pixel in the first direction in the plan view,
a seventh unit pixel adjacent to the fifth unit pixel in the second direction in the plan view, and
an eighth unit pixel adjacent to the sixth unit pixel in the second direction in the plan view and adjacent to the seventh unit pixel in the first direction in the plan view;
a third isolation trench in the substrate, the third isolation trench between the fifth unit pixel and the eighth unit pixel; and
a second color filter on the second surface of the substrate, the second color filter covering the second pixel group,
wherein the first color filter has a first color and the second color filter has a second color different from the first color.

10. An image sensor comprising:
a substrate including a first surface and a second surface opposed to each other;
a first isolation trench defining a plurality of pixel groups in the substrate, each of the pixel groups includes a plurality of unit pixels;
a second isolation trench in each of the pixel groups, the second isolation trench extending from the second surface and is spaced apart from the first surface;
a photoelectric conversion area in each of the unit pixels;
circuit elements on the first surface of the substrate; and
color filters on the second surface of the substrate,
the plurality of unit pixels including a first unit pixel, a second unit pixel adjacent to the first unit pixel in a first direction, and a third unit pixel adjacent to the first unit pixel in a second direction intersecting the first direction,
the second isolation trench between the second unit pixel and the third unit pixel.

11. The image sensor of claim 10, wherein
the plurality of pixel groups includes a first pixel group, a second pixel group adjacent to the first pixel group in the first direction, and a third pixel group adjacent to the first pixel group in the second direction, and
the color filters include:
a first color filter having a first color and covering the first pixel group;
a second color filter having a second color different from the first color and covering the second pixel group; and
a third color filter having a third color different from the first color and the second color and covering the third pixel group.

12. The image sensor of claim 10, wherein a width of the first isolation trench decreases as the first isolation trench extends from the first surface toward the second surface.

13. The image sensor of claim 12, wherein the first isolation trench extends from the first surface to the second surface.

14. The image sensor of claim 12, wherein the first isolation trench includes:
a filling pattern including a conductive material; and
a spacer film extending along a side surface of the filling pattern.

15. The image sensor of claim 14, wherein a depth of the second isolation trench from the second surface is smaller than a depth of the first isolation trench from the second surface.

16. The image sensor of claim 14, wherein the first isolation trench and the second isolation trench include different materials from each other.

17. The image sensor of claim 9, wherein the second isolation trench includes:
a first extension extending in the second direction and between the first unit pixel and the second unit pixel; and
a second extension extending in the first direction and between the first unit pixel and the third unit pixel.

18. An image sensor comprising:
a substrate including a first surface and a second surface opposed to each other;
a first pixel group in the substrate, the first pixel group including a first unit pixel, a second unit pixel adjacent to the first unit pixel in a first direction, a third unit pixel adjacent to the first unit pixel in a second direction intersecting the first direction, and a fourth unit pixel adjacent to the second unit pixel in the second direction and adjacent to the third unit pixel in the first direction;
a photoelectric conversion area in each of the first to fourth unit pixels;
a first isolation trench in the substrate, the first isolation trench surrounding the first pixel group;
a second isolation trench in the substrate, the second isolation trench between the first unit pixel and the fourth unit pixel;
a floating diffusion area extending from the first surface in the substrate, at least a portion of the floating diffusion area overlapping the second isolation trench in a third direction intersecting the first direction and the second direction;
a transfer transistor on the first surface of each of the first to fourth unit pixels, the transfer transistor being adjacent to the floating diffusion area;
a first color filter on the second surface of the substrate, the first color filter covering the first pixel group and having a first color; and
a micro lens on the first color filter,
the second isolation trench extending from the second surface and is spaced apart from the floating diffusion area.

19. The image sensor of claim 18, wherein a depth of the second isolation trench is in a range of 60% to 80% of a thickness of the substrate.

20. The image sensor of claim 18, wherein a spacing between the second isolation trench and the first surface is between 1 μm and 10 μm.
